(19) United States
(12) Patent Application Publication
(10) Pub. No.: US 2018/0152185 A1
(43) Pub. Date: May 31, 2018

(54) OPERATION DETECTION DEVICE

(71) Applicant: KABUSHIKI KAISHA TOKAI RIKA DENKI SEISAKUSHO, Aichi (JP)

(72) Inventor: Junji KAWAHATA, Aichi (JP)

(73) Assignee: KABUSHIKI KAISHA TOKAI RIKA DENKI SEISAKUSHO, Aichi (JP)

(21) Appl. No.: 15/572,322

(22) PCT Filed: May 12, 2016
(86) PCT No.: PCT/JP2016/064101

§ 371 Date: Nov. 7, 2017

(30) Foreign Application Priority Data
May 14, 2015 (JP) 2015-099061

(51) Int. Cl. H03K 17/96; H01H 36/00; B62D 1/04; G01R 27/26; G01V 3/08

(52) U.S. Cl. CPC H03K 17/962; H01H 36/00; G01V 3/08; G01R 27/2605; B62D 1/04

(57) ABSTRACT

An operation detection device includes a control unit configured to use a detection threshold value and detect whether or not a particular operation has been performed and a threshold value correction unit configured to correct the detection threshold value to a first corrected detection threshold value that is less than the detection threshold value when the control unit detects that the particular operation has not been performed under a situation in which the particular operation is presumed to have been performed.

### TECHNICAL FIELD

The present invention relates to an operation detection device.

### BACKGROUND ART

A vehicle in which a drive assist system is installed includes a capacitance sensor to detect whether or not a driver is holding a steering wheel (for example, refer to patent document 1).

As shown in FIG. 3, when steering wheel holding detection is performed with the capacitance sensor, a detection threshold value for steering wheel holding includes a margin to prevent erroneous detection of noise. This limits situations in which the amount of the change in capacitance reaches the detection threshold value when noise changes the capacitance. Further, when the driver is holding the steering wheel, the amount of change in capacitance reaches the detection threshold value. Thus, the holding of the steering wheel is detected.

### PRIOR ART DOCUMENT

### Patent Document

Patent Document 1: Japanese Laid-Open Patent Publication No. 2014-190856

### SUMMARY OF THE INVENTION

### Problems that are to be Solved by the Invention

As shown in FIG. 4, depending on the use case, the amount of change in capacitance may be small and may not reach the detection threshold value even though the steering wheel is being held. For example, when the hands of the driver are small or when the driver is wearing gloves, the holding of the steering wheel may not be detected. When the drive assist system is active, the drive assist system may be cancelled if the holding of the steering wheel cannot be detected.

It is an object of the present invention to provide an operation detection device that improves the detection accuracy of operation detection.

### Means for Solving the Problem

One aspect of the present invention is an operation detection device. The operation detection device includes a control unit configured to use a detection threshold value and detect whether or not a particular operation has been performed and a threshold value correction unit configured to correct the detection threshold value to a first corrected detection threshold value that is less than the detection threshold value when the control unit detects that the particular operation has not been performed under a situation in which the particular operation is presumed to have been performed.

One aspect of the present invention is a system that detects whether or not a particular operation is performed. The system includes a processor and a memory connected to the processor. The memory stores a command executable by the processor. When the instruction is executed, the processor is operable to perform detecting whether or not the particular operation has been performed using a detection threshold value, correcting the detection threshold value to a corrected detection threshold value that is less than the detection threshold value when detecting that the particular operation has not been performed under a situation in which the particular operation is presumed to have been performed, and detecting whether or not the particular operation has been performed using the corrected detection threshold value.

### Effect of the Invention

The present invention improves the detection accuracy of operation detection.

### BRIEF DESCRIPTION OF THE DRAWINGS

FIG. 1 is a block diagram showing the configuration of a steering wheel holding detection device.

FIG. 2 is a graph showing the capacitance change amount with respect to time, in which FIG. 2A is a graph showing that holding cannot be detected, and FIG. 2B is a graph showing that holding can be detected through threshold value correction.

FIG. 3 is a graph showing the principle of steering wheel holding detection.

FIG. 4 is a graph showing that holding cannot be detected.

### EMBODIMENTS OF THE INVENTION

One embodiment of an operation detection device will now be described.

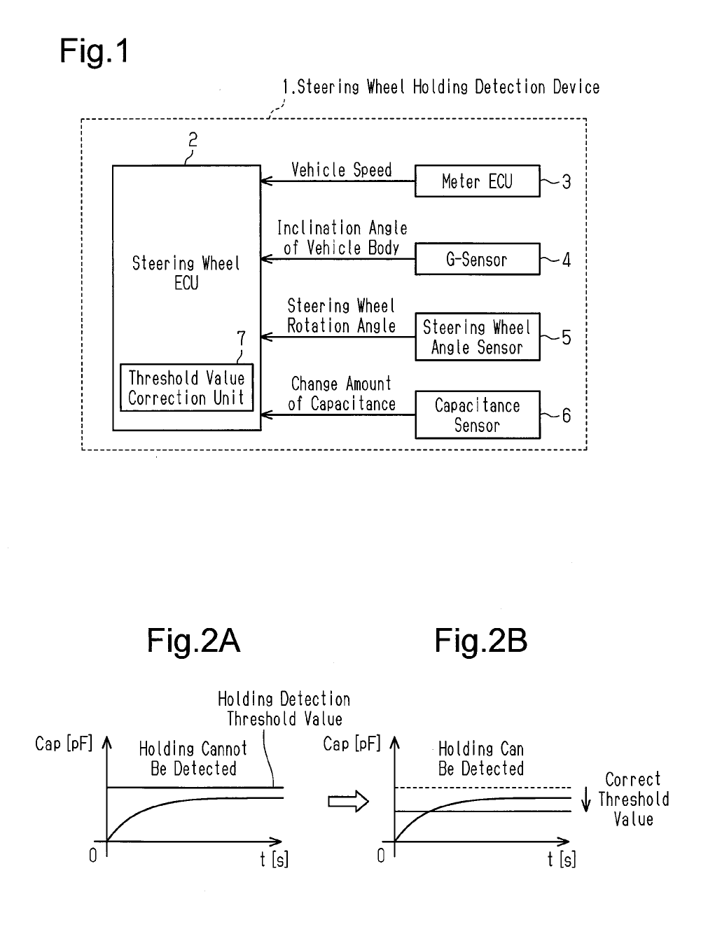

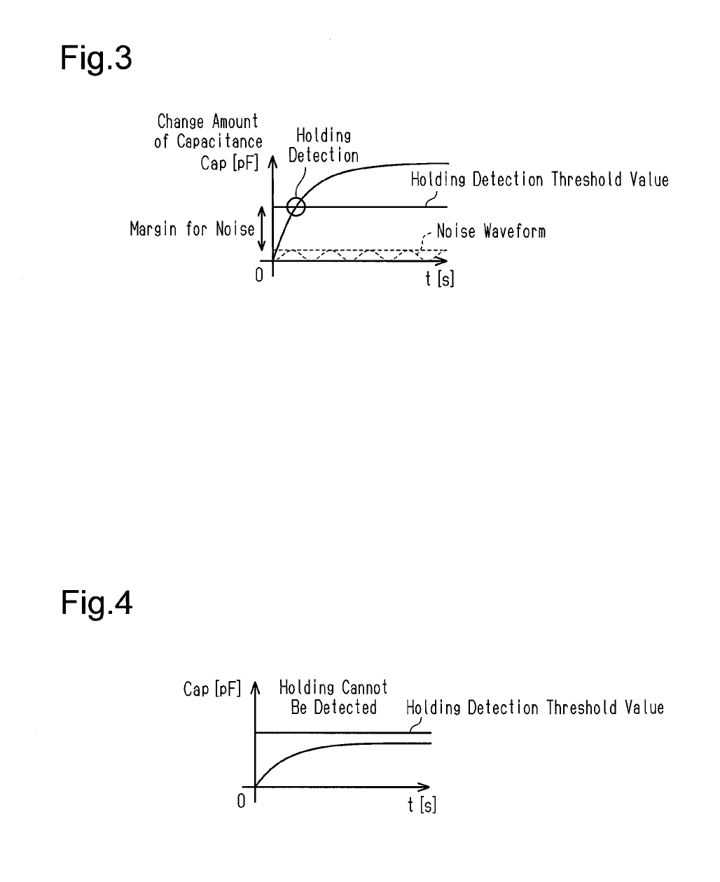

As shown in FIG. 1, a steering wheel holding detection device 1, which is one example of an operation detection device, includes a steering wheel electronic control unit 2 (ECU) that centrally controls a steering wheel. The steering wheel ECU 2 corresponds to a control unit. The control related to the steering wheel includes control for detecting whether or not a driver is holding the steering wheel.

A meter ECU 3 is connected to the steering wheel ECU 2. The meter ECU 3 obtains vehicle speed information from a vehicle speed sensor and generates a signal indicating the obtained vehicle speed. The steering wheel ECU 2 can recognize the vehicle speed based on the signal from the meter ECU 3.

A G-sensor 4 is connected to the steering wheel ECU 2. The G-sensor 4 detects an inclination angle of a vehicle body and generates a signal indicating the detected inclination angle of the vehicle body. The steering wheel ECU 2 can recognize the inclination angle of the vehicle body based on the signal from the G-sensor 4. The G-sensor 4 is an acceleration sensor.

A steering wheel angle sensor 5 is connected to the steering wheel ECU 2. The steering wheel angle sensor 5 detects a steering wheel rotation angle and generates a signal indicating the detected steering wheel rotation angle. The steering wheel ECU 2 can recognize the steering wheel rotation angle based on the signal from the steering wheel angle sensor 5.

A capacitance sensor 6 is connected to the steering wheel ECU 2. The capacitance sensor 6 detects the amount of change in capacitance and generates a signal indicating the detected change amount of the capacitance. The steering wheel ECU 2 determines whether or not the change amount of the capacitance has reached a detection threshold value based on the signal from the capacitance sensor 6 and determines that the driver is holding the steering wheel when the change amount of the capacitance reaches the detection threshold value (affirmative determination).

The steering wheel ECU 2 includes a threshold value correction unit 7 that corrects a detection threshold value when holding detection is negated under a situation in which the vehicle speed, the vehicle body inclination angle, and the steering wheel rotation angle are exceeding predetermined values. For example, the threshold value correction unit 7 lowers the detection threshold value when holding detection is negated under a situation in which the vehicle speed exceeds 50 km/h, the vehicle body inclination angle exceeds 3 degrees, and the steering wheel rotation angle exceeds 10 degrees. When the detection threshold value is corrected by the threshold value correction unit 7, the corrected detection threshold value is used to perform holding detection.

The situation satisfying the above three AND conditions is a situation in which the steering wheel can be presumed as being held. When the steering wheel ECU 2 cannot detect holding with the initial detection threshold value under such a situation, the steering wheel ECU 2 corrects the detection threshold value and performs holding detection again using the corrected detection threshold value. When the steering wheel ECU 2 detects holding, the drive assist system continues to be active.

More specifically, in the present embodiment, the steering wheel holding detection device 1 includes the control unit 2 and the threshold value correction unit 7. The control unit 2 is configured to use a detection threshold value and detect whether or not a particular operation has been performed. The threshold value correction unit 7 is configured to correct the detection threshold value to a corrected detection threshold value that is less than the detection threshold value when the control unit 2 detects that a particular operation has not been performed under a situation in which the particular operation can be presumed to have been performed. It is preferred that the control unit 2 obtain a measurement value of a first characteristic related to a particular operation, compare the measurement value of the first characteristic with the detection threshold value, and detect whether or not the particular operation has been performed from the comparison result. Further, it is preferred that the threshold value correction unit 7 obtain measurement values of a plurality of second characteristics related to the particular operation and presume that the particular operation has been performed based on the measurement values of the plurality of second characteristics.

The operation of the steering wheel holding detection device 1 will now be described.

As shown in FIG. 2A, when the hands of the driver are small or when the driver is wearing gloves, even if holding detection is performed under a situation in which the holding of the steering wheel is presumed to be detected, the change amount of capacitance is small and does not reach the initial detection threshold value. In the prior art, threshold value correction is not performed. Thus, holding cannot be detected under the above situation. This cancels the drive assist system.

In this regard, in the present example, as shown in FIG. 2B, when holding cannot be detected under the above situation, the steering wheel ECU 2 performs threshold value correction to lower the detection threshold value. For example, the detection threshold value is reduced to a value that is one-half of the initial detection threshold value, which is shown by the broken line. However, the corrected detection threshold value is set to be greater than or equal to the minimum value of a detection threshold value in which a margin for a noise level set in advance is added. Thus, the change amount of capacitance reaches the detection threshold value, and the holding under the above situation is detected. Accordingly, the drive assist system continues to be active.

After retrying the holding detection once using the corrected detection threshold value, the detection threshold value is returned to the initial detection threshold value.

As described above, the present embodiment has the following advantages.

(1) The probability of steering wheel holding detection being affirmed is increased by performing threshold value correction that lowers the detection threshold value. This improves the detection accuracy of the steering wheel holding detection.

(2) The detection threshold value subsequent to the correction by threshold value correction is set to a detection threshold value that is greater than or equal to the minimum value of a detection threshold value having a margin for a noise level. This configuration improves the detection accuracy while maintaining the normal noise resistance.

(3) Threshold value correction is not performed under a situation in which holding detection is presumed not to be affirmed. Thus, subsequent operations that would be based on the affirmation of the holding detection are not performed more than necessary.

(4) Threshold value correction is performed only once. This quickly determines subsequent operation modes based on affirmation or negation of the holding detection.

(5) The detection threshold value can be automatically corrected.

The above embodiment may be modified as described below.

Threshold value correction may be performed a number of times.

In the configuration in which the threshold value correction is performed a number of times, while using a detection value corrected by the threshold value correction, the detection threshold value may be gradually reduced in a range that is greater than or equal to the minimum value of the detection threshold value whenever the holding detection is negated. In this configuration, gradual reduction of the detection threshold value limits erroneous detection of noise at an initial stage. This increases the noise resistance.

More specifically, when the threshold value correction unit 7 corrects the detection threshold value to a first corrected detection threshold value, the control unit uses the first corrected detection threshold value to detect whether or not a particular operation has been performed. Further, when the control unit 2 detects that the particular operation has not been performed, the threshold value correction unit 7 corrects the first corrected detection threshold value to a second corrected detection threshold value that is less than the first corrected detection threshold value and greater than or equal to minimum value of the detection threshold value.

In the configuration in which the threshold value correction is performed a number of times, instead of the configuration in which a detection threshold value is gradually reduced, the threshold value correction may be performed a number of times using the same detection threshold value. This configuration improves the detection accuracy while obtaining a high noise resistance in, for example, a use case in which the hands are temporarily separated from the steering wheel.

More specifically, when the threshold value correction unit 7 corrects the detection threshold value to the first corrected detection threshold value, the control unit 2 uses the first corrected detection threshold value and detects whether or not the particular operation has been performed. Further, when the control unit 2 detects that the particular operation has not been performed, the threshold value correction unit 7 uses the first corrected detection threshold value and detects again whether or not the particular operation has been performed.

In a configuration in which the threshold value correction is performed a number of times, a configuration that performs the threshold value correction within a specified number of times may be employed.

The detection threshold value corrected by the first threshold value detection may be set to the minimum value of the detection threshold value. This configuration increases the probability of holding detection being affirmed by the first threshold value correction. This accelerates the time at which holding detection can be affirmed.

The situation in which holding of the steering wheel is presumed to be detected may include the depression amount of an accelerator pedal exceeding a fixed value.

Instead of detecting whether or not the driver is holding the steering wheel, a detection threshold value may be used to detect whether or not the driver is seated on a driver seat.

The process executed by the control unit 2 of the above embodiment can be achieved by a dedicated hardware circuit or an instruction (software) executed by a processor such as a CPU. When software is used, the process can execute an operation detection process by reading an instruction stored in a non-transitory computer readable medium (for example, working memory such as RAM). In this case, a system that detects a particular operation includes a processor and a memory connected to the processor. The memory stores a command executable by the processor. When the instruction is executed, the processor is operable to perform detecting whether or not the particular operation has been performed using a detection threshold value, correcting the detection threshold value to a corrected detection threshold value that is less than the detection threshold value when detecting that the particular operation has not been performed under a situation in which the particular operation is presumed to have been performed, and detecting whether or not the particular operation has been performed using the corrected detection threshold value. It is preferred that the system further include a first sensor that is connected to the processor and measures a first characteristic related to the particular operation and a plurality of second sensors that are connected to the processor and measure a plurality of second characteristics related to the particular operation that differ from the first characteristic, It is preferred that the detecting whether or not the particular operation has been performed using the detection threshold value include obtaining a measurement value of a first characteristic from the first sensor, comparing the obtained measurement value of the first characteristic with the detection threshold value, and detecting that the particular operation has been performed when the measurement value of the first characteristic is greater than the detection threshold value. It is preferred that presuming that the particular operation has been performed include obtaining measurement values of a plurality of second characteristics related to the particular operation and the presuming that the particular operation has been performed based on the obtained measurement values of the plurality of second characteristics. It is preferred that the particular operation include a driver of a vehicle holding a steering wheel. It is preferred that the first sensor include a capacitance sensor that is coupled to the steering wheel of the vehicle and detects capacitance as the first characteristic. It is preferred that the plurality of second sensors include a vehicle speed sensor, an acceleration sensor, and a steering wheel angle sensor that detect vehicle speed, inclination angle of a vehicle body, and steering wheel rotation angle as the plurality of second characteristics.

1. An operation detection device comprising:
a control unit configured to use a detection threshold value and detect whether or not a particular operation has been performed; and
a threshold value correction unit configured to correct the detection threshold value to a first corrected detection threshold value that is less than the detection threshold value when the control unit detects that the particular operation has not been performed under a situation in which the particular operation is presumed to have been performed.

2. The operation detection device according to claim 1, wherein the first corrected detection threshold value is set to be greater than a minimum value in which a margin for a noise level set in advance is added.

3. The operation detection device according to claim 2, wherein
when the threshold value correction unit corrects the detection threshold value to the first corrected detection threshold value, the control unit uses the first corrected detection threshold value and detects whether or not the particular operation has been performed, and
when the control unit detects that the particular operation has not been performed, the threshold value correction unit corrects the first corrected detection threshold value to a second corrected detection threshold value that is less than the first corrected detection threshold value and greater than or equal to the minimum value of the detection threshold value.

4. The operation detection device according to claim 1, wherein
when the threshold value correction unit corrects the detection threshold value to the first corrected detection threshold value, the control unit uses the first corrected detection threshold value and detects whether or not the particular operation has been performed, and
when the control unit detects that the particular operation has not been performed, the threshold value correction unit uses the first corrected detection threshold value and detects again whether or not the particular operation has been performed.

5. The operation detection device according to claim 2, wherein the threshold value correction unit sets the first corrected detection threshold value to the minimum value of the detection threshold value.

6. The operation detection device according to claim 1, wherein
the control unit obtains a measurement value of a first characteristic related to the particular operation, compares the measurement value of the first characteristic with the detection threshold value, and detects whether or not the particular operation has been performed from the comparison result, and
the threshold value correction unit obtains measurement values of a plurality of second characteristics related to the particular operation and presumes that the particular operation has been performed based on the measurement values of the plurality of second characteristics.

7. The operation detection device according to claim 3, wherein the threshold value correction unit executes a threshold value correction process within a predetermined number of times.

8. A system that detects whether or not a particular operation is performed, the system comprising:
a processor; and
a memory connected to the processor, wherein the memory stores a command executable by the processor, wherein
when the instruction is executed, the processor is operable to perform:
detecting whether or not the particular operation has been performed using a detection threshold value;
correcting the detection threshold value to a corrected detection threshold value that is less than the detection threshold value when detecting that the particular operation has not been performed under a situation in which the particular operation is presumed to have been performed; and
detecting whether or not the particular operation has been performed using the corrected detection threshold value.

9. The system according to claim 8, further comprising:
a first sensor connected to the processor, wherein the first sensor measures a first characteristic related to the particular operation; and
a plurality of second sensors connected to the processor, wherein the plurality of second sensors measure a plurality of second characteristics related to the particular operation that differ from the first characteristic, wherein
the detecting whether or not the particular operation has been performed using the detection threshold value includes
obtaining a measurement value of a first characteristic from the first sensor,
comparing the obtained measurement value of the first characteristic with the detection threshold value, and
detecting that the particular operation has been performed when the measurement value of the first characteristic is greater than the detection threshold value, and
presuming that the particular operation has been performed includes
obtaining measurement values of a plurality of second characteristics related to the particular operation, and
the presuming that the particular operation has been performed based on the obtained measurement values of the plurality of second characteristics.

10. The system according to claim 8, wherein
the particular operation includes holding a steering wheel by a driver of a vehicle,
the first sensor includes a capacitance sensor coupled to the steering wheel of the vehicle, wherein the capacitance sensor detects capacitance as the first characteristic, and
the plurality of second sensors include a vehicle speed sensor, an acceleration sensor, and a steering wheel angle sensor that detect vehicle speed, inclination angle of a vehicle body, and steering wheel rotation angle as the plurality of second characteristics.
